(19) United States
(12) Patent Application Publication
(10) Pub. No.: US 2022/0014350 A1
(43) Pub. Date: Jan. 13, 2022

(54) PHASE-SYNCHRONIZING CIRCUIT

(71) Applicant: MITSUBISHI ELECTRIC CORPORATION, Tokyo (JP)

(72) Inventors: Kae MORITA, Tokyo (JP); Kenichi TAJIMA, Tokyo (JP); Hideyuki NAKAMIZO, Tokyo (JP); Hiroyuki MIZUTANI, Tokyo (JP); Osamu WADA, Tokyo (JP)

(73) Assignee: MITSUBISHI ELECTRIC CORPORATION, Tokyo (JP)

(21) Appl. No.: 17/482,685

(22) Filed: Sep. 23, 2021

Related U.S. Application Data
(63) Continuation of application No. PCT/JP2019/017664, filed on Apr. 25, 2019.

(51) Int. Cl. H04L 7/02; H03L 7/00

(52) U.S. Cl. CPC H04L 7/02; H03L 7/00

(57) ABSTRACT

The phase-synchronizing circuit according to the present disclosure includes: a signal source to output a signal; a signal separator to output part of the signal from the signal source as a transmission signal and receive a reflected signal of the transmission signal; a first phase controller to change a phase of the transmission signal from the signal separator according to a control signal; a signal reflector to pass the transmission signal from the first phase controller as an output signal and output part of the output signal as the reflected signal; and a phase comparator to receive part of the signal from the signal source as a reference signal, compare a phase of the reference signal with a phase of the reflected signal from the signal reflector, and output the control signal corresponding to a phase difference between the reference signal and the reflected signal to the first phase controller.

### CROSS REFERENCE TO RELATED APPLICATIONS

This application is a Continuation of PCT International Application No. PCT/JP2019/017664 filed on Apr. 25, 2019, which is hereby expressly incorporated by reference into the present application.

### TECHNICAL FIELD

The present disclosure relates to a phase-synchronizing circuit.

### BACKGROUND TECHNOLOGY

In general, when microwaves propagate through a phase-synchronizing circuit, temperature change occurring around a cable and vibration transmitted to the cable cause the cable to expand and contract; in other words, the cable length varies. Due to such transmission length variation of the cable, phase fluctuation arises in signals after transmitted through the cable. Therefore, in order to improve the phase stability of the output signals, it is necessary to compensate for the phase fluctuation caused by the cable length variation.

In order to solve the above-mentioned problem, a conventional phase-synchronizing circuit compares a signal carrying the phase fluctuation caused by the cable length variation with a signal before cable transmission to compensate for the fluctuation (Patent Document 1).

The conventional phase-synchronizing circuit includes a microwave signal source, a signal separator, a delay controller, a phase comparator, a delay controller, a cable, and a signal reflector. The signal outputted from the microwave signal source is inputted to the signal separator and the phase comparator. The signal inputted to the signal separator is outputted with its phase changed therein and inputted to the delay controller. The signal inputted to the delay controller is outputted therefrom with a phase shift in accordance with a control signal from the phase comparator, and then inputted to the signal reflector via the cable. The signal inputted to the signal reflector is passed therethrough to be outputted as the output signal of this phase-synchronizing circuit. Part of the signal inputted to the signal reflector (input signals) is reflected. The signal reflected by the signal reflector (reflected signals) is inputted to the phase comparator via the cable, the delay controller, and the signal separator.

The phase comparator compares the phase difference between the reflected signal (received via the cable, the delay controller, and the signal separator) and the signal received from the microwave signal source, and then outputs the control signal to the delay controller in such a way that the phase difference is constant (for example, the phase difference=0 degree).

In this way, the conventional phase-synchronizing circuit is configured to perform feedback control. Therefore, even though the transmission length of the cable connecting the delay controller and the signal reflector varies due to temperature change or vibration, the phase fluctuation can be compensated.

### PRIOR ART LITERATURE

### Patent Documents

Japanese Unexamined Patent Publication No. 2014-11561

### SUMMARY OF THE INVENTION

### Problems to be Solved by the Invention

In the phase-synchronizing circuit disclosed above in Patent Document 1, the passing phase of the signal reflector is added to the signal being outputted from the signal reflector when the signal passes through the signal reflector. Therefore, a phase difference occurs between the phase of the signal inputted to the phase-synchronizing circuit and the phase of the signal outputted from the phase-synchronizing circuit. Therefore, there is a problem that the phase of the signal outputted from the phase-synchronizing circuit cannot be matched with the phase of the signal inputted to the phase-synchronizing circuit.

The present invention is devised to solve the above-mentioned problem and, in contrast to the conventional phase-synchronizing circuit, to provide a phase-synchronizing circuit that can match the phase of the input signal inputted to the phase-synchronizing circuit with the phase of the output signal outputted from the phase-synchronizing circuit.

### Means for Solving the Problems

The phase-synchronizing circuit according to the present disclosure includes: a signal source to output a signal; a signal separator to output part of the signal outputted from the signal source as a transmission signal and receive a reflected signal of the transmission signal; a first phase controller to change a phase of the transmission signal outputted from the signal separator in accordance with a control signal; a signal reflector to pass the transmission signal outputted from the first phase controller as an output signal and output part of the output signal as the reflected signal; and a phase comparator to receive part of the signal outputted from the signal source as a reference signal, compare a phase of the reference signal with a phase of the reflected signal outputted from the signal reflector via the first phase controller and the signal separator, and output the control signal corresponding to a phase difference between the reference signal and the reflected signal to the first phase controller.

### Effects of the Invention

According to the present disclosure, the phase of the input signal can be matched with the phase of the output signal of the phase-synchronizing circuit.

### BRIEF DESCRIPTION OF THE DRAWINGS

FIG. 1 is a diagram showing a configuration example of a phase-synchronizing circuit according to Embodiment 1.

FIG. 2 is a configuration diagram of a 90 degree hybrid used for a signal separator according to Embodiment 1.

FIG. 3 is a diagram showing a configuration example of a phase-synchronizing circuit according to Embodiment 2.

FIG. 4 is a diagram showing another configuration example of a signal reflector according to Embodiment 2.

### EMBODIMENTS OF THE INVENTION

### Embodiment 1

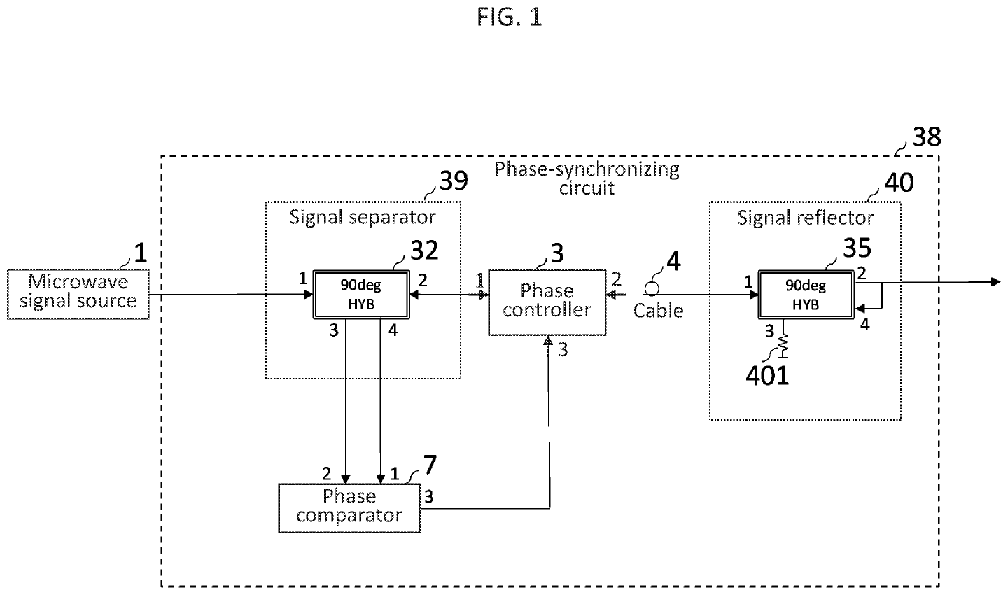

FIG. 1 is a diagram showing a configuration example of a phase-synchronizing circuit according to Embodiment 1.

This phase-synchronizing circuit includes a signal separator 39 (an example of a signal separator), a phase controller 3 (an example of a first phase controller), a cable 4, a signal reflector 40 (an example of a signal reflector), and a phase comparator 7 (an example of a phase comparator).

Hereinafter, Embodiment 1 according to the present disclosure will be described in detail with reference to the drawings. In each figure, the same or corresponding components are designated by the same reference numerals. In each figure, the cable is shown with a solid line.

A microwave signal source 1 (an example of a signal source) outputs reference signal to the signal separator 39.

For example, a crystal oscillator ensuring accurate output frequency is used for the microwave signal source 1.

The signal separator 39 divides the reference signal outputted from the microwave signal source 1 into two, outputs one divided reference signal to the phase comparator 7 as the reference signal of the phase-synchronizing circuit, outputs the other divided reference signal to the phase controller 3 as a transmission signal, and outputs the reflected signal reflected by the signal reflector 40 to the phase comparator 7. The reflected signal is a transmitted signal which is outputted from the signal separator 39 and reflected by the signal reflector 40. For example, for the signal separator 39, a 90 degree hybrid with coupled lines is used.

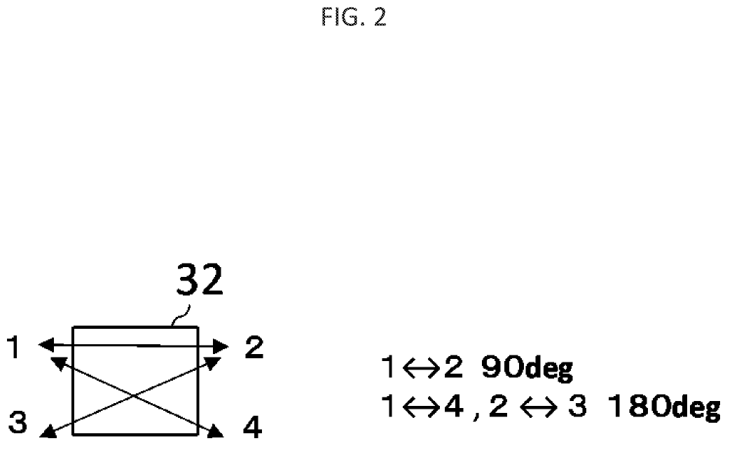

FIG. 2 is a configuration diagram of a 90 degree hybrid 32 used for the signal separator 39 according to Embodiment 1. Passing through the 90 degree hybrid 32 (an example of a first 90 degree hybrid) from a first terminal (input terminal) to a second terminal (first output terminal) changes the signal phase by 90 degrees. Also, passing through the 90 degree hybrid 32 from the first terminal (input terminal) to a fourth terminal (second output terminal) or from the second terminal (first output terminal) to a third terminal (isolation terminal) changes the signal phase by 180 degrees. In the following, Embodiment 1 will be explained on the premise that the 90 degree hybrid 32 is used for the signal separator 39.

The phase controller 3 performs the following tasks in accordance with the control signal outputted from the phase comparator 7: to change the phase of transmission signal outputted from the signal separator 39; to output the transmission signal with the changed phase to the signal reflector 40; to change the phase of the reflected signal reflected by the signal reflector 40; and to output the reflected signal with the changed phase to the signal separator 39. The phase controller 3, which has three terminals, changes the phase of the signal inputted to a first terminal (input terminal) in accordance with the control signal inputted to a third terminal (control terminal), and outputs the signal with the changed phase from a second terminal (output terminal). When a signal is inputted to the second terminal (output terminal) of the phase controller 3, the phase controller 3 changes, in accordance with the control signal, the phase of the inputted signal by the same amount as when it is outputted from the first terminal to the second terminal, and outputs it from the first terminal (input terminal). For example, a phase controller including a silicon integrated circuit (IC) is used for the phase controller 3.

The cable 4, which connects the phase controller 3 and the signal reflector 40, outputs to the signal reflector 40 the transmission signal outputted from the phase controller 3. On the other hand, the cable 4 outputs to the phase controller 3 the reflected signal outputted from the signal reflector 40. For example, a coaxial cable or the like is used for the cable 4.

The signal reflector 40 outputs to the outside part of the transmission signal outputted from the phase controller 3 as the output signal of the phase-synchronizing circuit, and also reflects part of the transmission signal to the phase controller 3 as the reflected signal. The signal reflector 40 has two terminals, and passing from a first terminal (input terminal) to a second terminal (output terminal) changes the signal phase by 90 degrees. The signal reflector 40 changes the phase of part of the transmission signal inputted to the first terminal (input terminal) by 270 degrees, and outputs it from the first terminal (input terminal) as the reflected signal. For example, a 90 degree hybrid with one end terminated is used for the signal reflector 40. The signal reflector 40 has a configuration in which a third terminal (isolation terminal) of a 90 degree hybrid 35 (an example of a second 90 degree hybrid) is terminated by a resistor 401, and the second terminal (first output terminal) and the fourth terminal (second output terminal) are connected to each other. The configuration of the 90 degree hybrid 35 is identical to that of the 90 degree hybrid shown in FIG. 2.

The phase comparator 7 compares the phase of the reference signal outputted from the signal separator 39 with the phase of the reflected signal reflected by the signal reflector 40, and outputs the control signal corresponding to the phase difference therebetween to the phase controller 3. The phase comparator 7, which has three terminals, compares the phase of the signal inputted to a first terminal (first input terminal) and the phase of the signal inputted to a second terminal (second input terminal), and outputs the control signal from a third terminal (output terminal) to the phase controller 3 so that the phase difference therebetween will be zero degree. For example, a phase comparator including a silicon IC is used for the phase comparator 7.

Next, the operation of the phase-synchronizing circuit according to Embodiment 1 of the present disclosure will be described with reference to FIG. 1.

The microwave signal source 1 outputs the reference signal to the signal separator 39.

The signal separator 39 changes the phase of the reference signal outputted from the microwave signal source 1 by 90 degrees, and outputs the signal with the changed phase from the second terminal to the phase controller 3 as the transmission signal. The signal separator 39 changes the phase of the reference signal outputted from the microwave signal source 1 by 180 degrees, and outputs the signal with the changed phase from the fourth terminal to the phase comparator 7.

The phase controller 3 changes the phase of the transmission signal outputted from the signal separator 39 in accordance with the control signal from the phase comparator 7, and outputs the transmission signal with the changed phase from the second terminal to the signal reflector 40 via the cable 4.

The signal reflector 40 outputs part of the transmission signal inputted from the first terminal to the outside as the output signal of this phase-synchronizing circuit. The signal reflector 40 inputs part of the output signal outputted from the second terminal to the fourth terminal, changes the phase of the inputted signal by 180 degrees, and outputs the signal with the changed phase from the first terminal as the reflected signal. The reflected signal outputted from the first terminal of the signal reflector 40 is inputted to the second terminal of the phase controller 3 via the cable 4.

The phase controller 3 changes the phase of the reflected signal outputted from the signal reflector 40 in accordance with the control signal outputted from the phase comparator 7, and outputs the reflected signal with the changed phase to the second terminal of the signal separator 39.

The signal separator 39 changes the phase of the reflected signal outputted from the phase controller 3 by 180 degrees and outputs the signal with the changed phase from the third terminal to the phase comparator 7.

The phase comparator 7 compares the phase of the reflected signal outputted from the signal separator 39 with the phase of the reference signal outputted from the signal separator 39, and outputs the control signal in accordance with the phase difference therebetween to the phase controller 3.

The phase controller 3 changes the phases of the transmission signal and the reflected signal in accordance with the control signal outputted from the phase comparator 7.

Such phase control as described above makes it possible to cancel the phase shift that occurs when the signal passes through the signal separator 39, the phase controller 3, the cable 4, and the signal reflector 40. As a result, the phase of the output signal can be matched with the phase of the input signal, which is the phase of the reference signal outputted from the microwave signal source 1.

The operation of this phase-synchronizing circuit will be described below using mathematical expressions.

The phase θₒᵤₜ of the output signal outputted from the phase-synchronizing circuit 38 is given by Equation (1). Here, let θ₀ be the initial phase of the reference signal outputted by the microwave signal source 1, θₜᵤₙₑ be the passing phase of the phase controller 3, and θ_{cable} be the passing phase of the cable 4.

[Equation 1]

θₒᵤₜ=θ₀+180+θₜᵤₙₑ+θ_{cable} (1)

Equation (2) shows the phase θ₁ of the reference signal outputted from the microwave signal source 1 to the phase comparator 7 via the signal separator 39 (90 degree hybrid 32).

[Equation 2]

θ₁=θ₀+180 (2)

Equation (3) shows the phase θ₂ of the reflected signal outputted from the first terminal of the signal reflector 40 (90 degree hybrid 35) to the phase comparator 7 via the cable 4, the phase controller 3, and the signal separator 39 (90 degree hybrid 32).

[Equation 3]

θ₂=θ₀+540+2θₜᵤₙₑ+2θ_{cable} (3)

The phase comparator 7 controls the phase controller 3 in such a way that the phase of the reference signal and the phase of the reflected signal, both outputted from the signal separator 39, are equal to each other. Therefore, θ₁=θ₂ holds in a steady state. Therefore, the following Equation (4) is obtained from Equation (2)=Equation (3).

[Equation 4]

180+θₜᵤₙₑ+θ_{cable}=0 (4)

Substituting Equation (4) into Equation (1) yields the following Equation (5).

[Equation 5]

θₒᵤₜ=θ₀ (5)

As can be seen from Equation (5), the phase of the reference signal inputted to the phase-synchronizing circuit 38 and the phase of the output signal outputted from the phase-synchronizing circuit 38 are equal.

As described above, according to Embodiment 1, a 90 degree hybrid is used for the signal separator 39 and the signal reflector 40; the signal reflector 40 is configured to output part of the output signal as the reflected signal; and the reflected signal and the output signal of the phase-synchronizing circuit are associated with each other. This makes it possible to match, in this phase-synchronizing circuit, the phase of the input signal (reference signal) with the phase of the output signal (transmission signal).

In Embodiment 1, a 90 degree hybrid is used for the signal separator 39 and the signal reflector 40, but following components may be used.

The signal separator 39 may be any component that changes the phase of the signal by θ_{α} degrees when the signal passes from the first terminal to the second terminal, and by 2θ_{α} degrees when the signal passes from the first terminal to the fourth terminal and when the signal passes from the second terminal to the third terminal.

The signal reflector 40 may be a component that changes the phase of the signal inputted to the first terminal by θ_{α} degrees to output it from the second terminal, and changes the phase of part of the signal inputted to the first terminal by 3θ_{α} degrees to output it from the first terminal.

Thus, the signal separator 39 and the signal reflector 40 do not have to be a 90 degree hybrid, but may be any component in which the phase shift amount from the first terminal to the third terminal is an integer multiple of the phase shift amount from the first terminal to the second terminal.

### Embodiment 2

In Embodiment 2, a configuration will be shown in which the phase of the output signal outputted from the phase-synchronizing circuit can be matched with the phase of the input signal inputted to the phase-synchronizing circuit even if the phase of the reflected signal changes due to partial leakage of the reference signal into the reflected signal output terminal, the partial leakage being caused by the limited isolation of the signal separator 39.

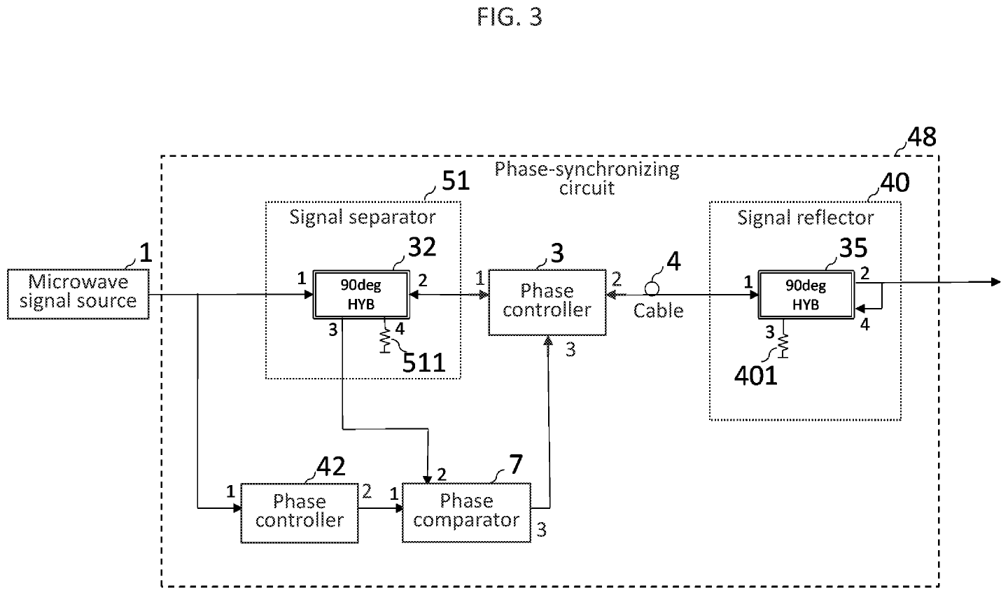

FIG. 3 is a diagram showing a configuration example of a phase-synchronizing circuit according to Embodiment 2 of the present disclosure.

Basic configurational changes from the phase-synchronizing circuit 38 according to Embodiment 1 to a phase-synchronizing circuit 48 shown in FIG. 3 according to Embodiment 2 is that a phase controller 42 (an example of a second phase controller) is added and the signal separator 39 is replaced with a signal separator 51. The components other than the phase controller 42 and the signal separator 51 are identical and marked with the same symbols, so that their descriptions will be omitted.

The signal separator 51 outputs to the phase controller 3 the signal outputted from the microwave signal source 1 as the transmission signal, and outputs to the phase comparator 7 the reflected signal outputted from the signal reflector 40 to the phase comparator 7. The signal separator 51, which has three terminals, changes the phase of the signal passing from a first terminal (input terminal) to a second terminal (first output terminal) by 90 degrees, and the phase of the signal passing from the second terminal (first output terminal) to a third terminal (isolation terminal) by 180 degrees. For example, for the signal separator 51, a 90 degree hybrid with coupled lines is used. Since the configuration of the 90 degree hybrid 32 is the same as that shown in FIG. 2, the description is omitted. The signal separator 51 can be realized by terminating a fourth terminal (second output terminal) of the 90 degree hybrid 32 with a resistor 511.

The phase controller 42 changes the phase of the reference signal outputted from the microwave signal source 1, and outputs the reference signal with the changed phase to the phase comparator 7. In the signal separator 51, the partial leakage of the reference signal into the isolation terminal causes a phase shift in the reflected signal. The phase controller 42 changes the phase of the reference signal by the phase shift amount occurring in the reflected signal. For example, a phase controller including a silicon IC is used for the phase controller 42.

Next, the operation of the phase-synchronizing circuit according to Embodiment 2 will be described with reference to FIG. 3.

The reference signal outputted from the microwave signal source 1 is inputted to the first terminal of the signal separator 51 and to the phase controller 42. The signal separator 51 splits the reference signal inputted to the first terminal into two. One split reference signal is absorbed by the resistor 511 in the signal separator 51.

The phase of the other split reference signal is changed by 90 degrees. The signal with the changed phase is outputted from the second terminal as the transmission signal and inputted to the phase controller 3.

The subsequent operations of the phase controller 3, the cable 4, and the signal reflector 40 are the same as those shown Embodiment 1, so that their descriptions are omitted. Part of the transmission signal is reflected by the signal reflector 40 as in Embodiment 1, and the reflected signal is inputted to the second terminal of the signal separator 51 via the cable 4 and the phase controller 3.

The signal separator 51 changes the phase of the reflected signal inputted to the second terminal by 180 degrees, and outputs the reflected signal with the changed phase by 180 degrees from the third terminal to the phase comparator 7.

On the other hand, the reference signal outputted from the microwave signal source 1 is inputted the phase controller 42. The phase controller 42 changes the phase of the reference signal by the amount corresponding to the phase shift of the reflected signal caused by the partial leakage of the reference signal into the isolation terminal occurring in the signal separator 51, and outputs the reference signal with the changed phase to the phase comparator 7. This makes it possible to compensate for the phase shift of the reflected signal due to the leakage of the reference signal. Since the subsequent operations are the same as those in Embodiment 1, their descriptions will be omitted.

Such a configuration as described above makes it possible to compensate for the phase shift of the reflected signal caused by the leakage of the reference signal, having entered the first terminal, into the third terminal in the 90 degree hybrid 32 of the signal separator 51, and thus to allow correct control of the phase controller 3.

The operation of the phase-synchronizing circuit 48 will be described below in view of the phase relationships of the signals.

The phase θₒᵤₜ₂ of the transmission signal outputted from the phase-synchronizing circuit 48 according to Embodiment 2 of the present disclosure is given by Equation (6). In Equation (6) shown below, θ₀ is the phase of the reference signal inputted to the signal separator 51.

[Equation 6]

θₒᵤₜ₂=θ₀+180+θₜᵤₙₑ+θ_{cable} (6)

The phase θ₂₁ of the reference signal outputted to the phase comparator 7 from the microwave signal source 1 via the phase controller 42 is given by Equation (7).

[Equation 7]

θ₂₁=θ₀+θᵥ (7)

Here, θᵥ represents the phase shift by the phase controller 42, and θᵥ=180+Δθ₀ holds. Δθ₀ represents the phase shift amount of the reflected signal caused by the leakage of the reference signal, having entered the first terminal, into the third terminal in the 90 degree hybrid 32.

The phase of the reflected signal θ₂₂ outputted from the signal reflector 40 and inputted to the phase comparator 7 via the cable 4, the phase controller 3, and the 90 degree hybrid 32 is given by Equation (8).

[Equation 8]

θ₂₂=θ₀+540+2θₜᵤₙₑ+2θ_{cable}+Δθ₀ (8)

The phase controller 42 controls the phase of the reference signal in such a way that θᵥ=180+Δθ₀ holds. The phase shift amount of the reflected signal Δθ₀ is obtained, for example, by measuring, with a network analyzer or the like, the phase of the reflected signal inputted to the second terminal of the 90 degree hybrid 32 and the phase of the reflected signal outputted from the third terminal thereof and calculating the phase difference therebetween.

When the phase-synchronizing circuit 48 is sufficiently converged, the phase (θ₂₁) of the reference signal and the phase (θ₂₂) of the reflected signal, which are compared by the phase comparator 7, are equal to each other, and θ₂₁=θ₂₂ holds. Therefore, the following Equation (9) is obtained from Equation (7)=Equation (8).

[Equation 9]

540+2θₜᵤₙₑ+2θ_{cable}+Δθ₀−θᵥ=0 (9)

Substituting Equation (9) into Equation (6) gives Equation (10).

[Equation 10]

θₒᵤₜ₂=θ₀−90+(θᵥ−Δθ₀)/2 (10)

Since θᵥ=180+Δθ₀ holds, substituting θᵥ into Equation (10) and rearranging it gives the following Equation (11).

[Equation 11]

θₒᵤₜ₂=θ₀ (11)

As can be seen from Equation (11), the phase of the transmission signal outputted from the phase-synchronizing circuit 48 and the phase of the reference signal inputted from the phase-synchronizing circuit 48 are equal.

As described so far, according to Embodiment 2, the phase of the output signal outputted from the phase-synchronizing circuit can be matched with the phase of the input signal inputted thereto even if the phase of the reflected signal changes due to the partial leakage of the reference signal into the reflected signal output terminal, the partial leakage being caused by the limited isolation of the 90 degree hybrid 32 of the signal separator 51. Also, in this phase-synchronizing circuit, if the reflected signal inputted to the second terminal of the 90 degree hybrid 32 leaks into the fourth terminal, this does not affect the reference signal inputted to the phase comparator 7 because the fourth terminal is terminated.

The signal separator 51 may be any component that changes the phase of the signal by θ_{α} degrees when it passes from the first terminal to the second terminal, and the phase of the signal by 2θ_{α} degrees when it passes from the second terminal to the third terminal. In that case, the phase controller 42 will adjust the phases so that the phase of the reference signal will be θ₀+2θ_{α}+Δθ₀.

In the above case, the signal reflector 40 may be any component that changes the phase of the signal inputted to the first terminal by θ_{α} degrees to output the signal with the changed phase from the second terminal and changes the phase of part of the signal inputted to the first terminal by 3θ_{α} degrees to output the part of the signal with the changed phase from the first terminal as the reflected signal.

Thus, the signal separator 51 and the signal reflector 40 do not have to be a 90 degree hybrid, but may be any component in which the phase shift amount from the first terminal to the third terminal is an integer multiple of the phase shift amount from the first terminal to the second terminal.

In addition, a signal reflector 41 with the following configuration can be used in place of the signal reflector 40.

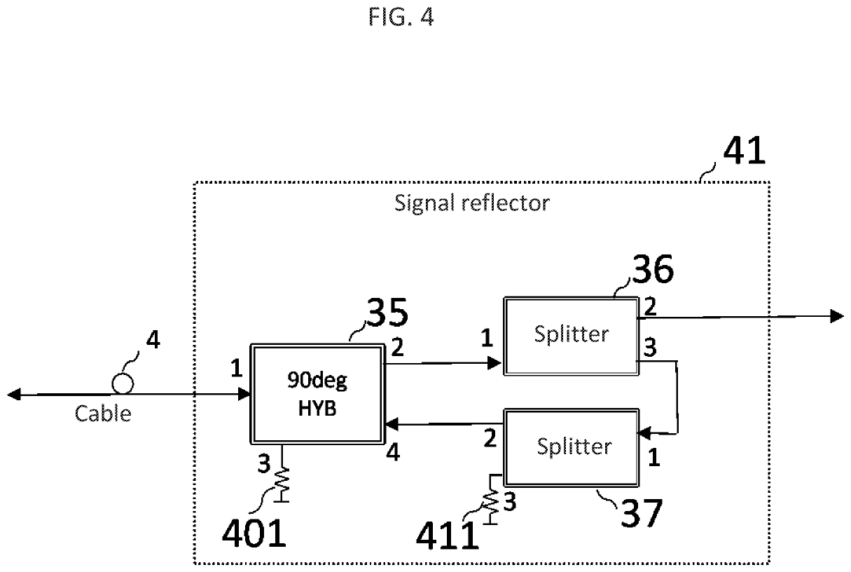

FIG. 4 shows a configuration example of the signal reflector 41.

The signal reflector 41 includes a 90 degree hybrid 35, a splitter 36 (an example of a first splitter), and a splitter 37 (an example of a second splitter).

The splitter 36 divides the transmission signal outputted from the 90 degree hybrid 35 into two, outputs one divided transmission signal as the output signal of this phase-synchronizing circuit, and outputs the other divided transmission signal to the splitter 37. The splitter 36, which has three terminals, divides the signal having entered the first terminal to output the divided signals from the second terminal and the third terminal. In doing so, the phase shift amount from the first terminal to the second terminal and the phase shift amount from the first terminal to the third terminal are equal. For the splitter 36, a splitter composed of transmission lines, a Wilkinson splitter, or the like is used.

The splitter 37, having the same passage characteristics as the splitter 36, divides the signal outputted from the splitter 36 into two, outputs one divided signal to the fourth terminal of the 90 degree hybrid 35 as the reflected signal of the transmission signal, and outputs the other divided signal to a resistor 411. The splitter 37, which has three terminals, gives the signal inputted to the first terminal the same phase shift amount as the splitter 36 gives, and outputs it from its second terminal to the fourth terminal of the 90 degree hybrid 35. The third terminal of the splitter 37 is terminated by the resistor 411.

As described above, the configuration of the signal reflector 41 which includes two splitters with the same phase shift makes it possible to cancel the effect of the phase shift given by the splitter 36 and thus to match the phase of the input signal with the phase of the output signal of the phase-synchronizing circuit 48.

The signal reflector 41 is described in Embodiment 2, but the signal reflector 41 may be used in the Embodiment 1.

### DESCRIPTION OF THE SYMBOLS

1 . . . microwave signal source,
3, 42 . . . phase controller,
4 . . . cable,
7 . . . phase comparator,
32, 35 . . . 90 degree hybrid,
36, 37 . . . splitter,
38, 48 . . . phase-synchronizing circuit,
39, 51 . . . signal separator,
40, 41 . . . signal reflector,
401, 411, 511 . . . resistor

1. A phase-synchronizing circuit comprising:
a signal source to output a signal;
a signal separator to output part of the signal outputted from the signal source as a transmission signal and receive a reflected signal of the transmission signal;
a first phase controller to change a phase of the transmission signal outputted from the signal separator in accordance with a control signal;
a signal reflector to pass the transmission signal outputted from the first phase controller as an output signal and output part of the output signal as the reflected signal; and
a phase comparator to receive part of the signal outputted from the signal source as a reference signal, compare a phase of the reference signal with a phase of the reflected signal outputted from the signal reflector via the first phase controller and the signal separator, and output the control signal corresponding to a phase difference between the reference signal and the reflected signal to the first phase controller.

2. The phase-synchronizing circuit according to claim 1, wherein the phase given to the reflected signal by the signal reflector is an integer multiple of a phase given to the transmission signal outputted from the signal reflector.

3. The phase-synchronizing circuit according to claim 2, wherein the phase given to the reflected signal by the signal separator is an integer multiple of the phase given to the signal by the signal separator.

4. The phase-synchronizing circuit according to claim 3, wherein the signal separator is a first 90 degree hybrid, outputs part of the signal outputted from the signal source from its output terminal to the first phase controller, and outputs the reflected signal inputted to its output terminal to the phase comparator.

5. The phase-synchronizing circuit according to claim 4, wherein the signal reflector includes a second 90 degree hybrid with its isolation terminal terminated, and part of the output signal outputted from its first output terminal is inputted to its second output terminal.

6. The phase-synchronizing circuit according to claim 5, further comprising:
a first splitter to divide the transmission signal outputted from the signal reflector; and
a second splitter having the same electrical characteristics as the first splitter, the second splitter further dividing the transmission signal divided by the first splitter and outputting part of the further divided transmission signal to the second output terminal of the second 90 degree hybrid.

7. The phase-synchronizing circuit according to claim 5, further comprising a second phase controller to control a phase of the signal outputted from the signal source and output the phase-controlled signal to the phase comparator as the reference signal.
